(19) United States
(12) Patent Application Publication
(10) Pub. No.: US 2026/0153810 A1
(43) Pub. Date: Jun. 4, 2026

(54) METHOD AND CONTROL DEVICE FOR PRODUCING AN OPTICAL SYSTEM FOR A LITHOGRAPHY APPARTUS

(71) Applicant: Carl Zeiss SMT GmbH, Oberkochen (DE)

(72) Inventors: Sabine BOGNER, Ulm (DE); Werner WEISS, Ulm (DE); Johannes SCHURER-KOCH, Heidenheim an der Brenz (DE)

(21) Appl. No.: 19/416,297

(22) Filed: Dec. 11, 2025

Related U.S. Application Data
(63) Continuation of application No. PCT/EP2024/051629, filed on Jan. 24, 2024.

(30) Foreign Application Priority Data
Jun. 12, 2023 (DE) 10 2023 205 439.6

(51) Int. Cl. G03F 7/00

(52) U.S. Cl. CPC G03F 7/70891; G03F 7/70075; G03F 7/70266

(57) ABSTRACT

A method for producing a lithography optical system having an optical component with an optically active surface and a substrate includes: 1) providing (S2), for a substrate of one or more optical components, a respective normalized distribution function (g, hₐ, h_{b}, h_{c}) of a zero crossing temperature (ZCT′, ZCTₐ, ZCT_{b}, ZCT_{c}) of a coefficient of thermal expansion of the respective substrate as a function of a location of the substrate, b) computer-implemented determining (S3), for each provided distribution function and for a plurality of predetermined mean zero crossing temperatures (Mⱼ) different from each other, an imaging error (Fᵢ) of the optical component and c) determining (S4) at least one selected mean zero-crossing temperature (M_{aw}) for the substrate of the optical component to be produced as that one of the plurality of mean zero-crossing temperatures for which the determined imaging error (Fᵢ) is smaller than a predetermined threshold value (SW).

### CROSS REFERENCE TO RELATED APPLICATIONS

This is a Continuation of International Application PCT/EP2024/051629, which has an international filing date of Jan. 24, 2024, and which claims the priority of German Patent Application 10 2023 205 439.6, filed Jun. 12, 2023. The disclosures of both applications are incorporated in their respective entireties into the present Continuation by reference.

### FIELD

The present invention relates to a method and a control device for producing an optical element for a lithography apparatus.

### BACKGROUND

Microlithography is used to produce microstructured components, such as for example integrated circuits. The microlithography process is carried out using a lithography apparatus comprising an illumination system and a projection system. The image of a mask (reticle) illuminated with the illumination system is projected with the projection system onto a substrate, for example a silicon wafer, which is coated with a light-sensitive layer (photoresist) and is arranged in the image plane of the projection system, in order to transfer the mask structure to the light-sensitive coating of the substrate.

Driven by the desire for ever smaller structures in the production of integrated circuits, extreme ultraviolet (EUV) lithography apparatuses which use light at a wavelength in the range of 0.1 nm to 30 nm, in particular 13.5 nm, are currently being developed. Since most materials absorb light at this wavelength, such EUV lithography apparatuses require the use of reflective optical units, i.e. mirrors, instead of refractive optical units, i.e. lens elements, as used previously.

A problem that arises in the process is that the mirrors heat up as a consequence of absorbing the radiation emitted by the EUV light source. This may lead to a thermal deformation of the mirrors. Furthermore, an optical coating of the mirrors might also degrade as a result of an increase in temperature. Both thermal deformations of the mirrors and damage to their optical coatings may adversely affect the imaging properties of the mirrors.

The imaging quality of projection systems of an EUV lithography apparatus depends greatly on the quality of the mirror material. A material with a very small coefficient of thermal expansion is used for mirror substrates in order to reduce imaging errors owing to heating of the mirrors. In particular, a deformation of the mirror material as a function of a temperature increase is minimal and/or zero at the so-called zero-crossing temperature of the coefficient of thermal expansion of the mirror material. The mean zero-crossing temperature of the mirror material and variations of the zero-crossing temperature within the mirror substrate volume have a direct influence on imaging errors caused by mirror heating.

### SUMMARY

Against this background, it is an object of the present invention to provide an improved method and an improved device for producing an optical system for a lithography apparatus.

Accordingly, a method for producing an optical system for a lithography apparatus is proposed. The optical system comprises an optical component having an optically active surface and a substrate. According to one formulation, the method comprises:
a) providing, for a substrate of one or more optical components, a respective normalized distribution function of a zero-crossing temperature of a coefficient of thermal expansion of the respective substrate as a function of a location of the substrate,
b) computer-implemented determining, for each provided distribution function and for a plurality of mutually different predetermined mean zero-crossing temperatures, of an imaging error of the optical system, and
c) determining at least one selected mean zero-crossing temperature for the substrate of the optical component to be produced as that one of the plurality of mean zero-crossing temperatures for which the determined imaging error is less than a predetermined threshold value.

The mean zero-crossing temperature of the coefficient of thermal expansion of the substrate material of the optical component can be set during the production of the substrate. Usually, the mean zero-crossing temperature of the substrate material is set depending on an expected operating temperature of the substrate.

A substrate material of an optical component usually has inhomogeneities which lead to an inhomogeneous distribution of the zero-crossing temperature over the substrate volume. This even applies to a high-performance substrate material. The inhomogeneous distribution of the zero-crossing temperature has an influence on the imaging properties of the optical component, and hence of the optical system with the optical component.

The applicant has determined that imaging errors of the optical system for a predefined (e.g. normalized) distribution of the zero-crossing temperature over the substrate volume of the optical component depend on the mean zero-crossing temperature of the substrate. Furthermore, the mean zero-crossing temperature of the substrate can still be adapted e.g. by heat treatment, even after the substrate has been produced (and thus for a zero-crossing temperature profile determined by production).

The proposed method now makes it possible to ascertain, for one or a plurality of predefined normalized distribution(s) of the zero-crossing temperature over the substrate volume, a favorable and/or optimal mean zero-crossing temperature of the substrate of the optical component with respect to the imaging quality.

The distribution function of the zero-crossing temperature of the coefficient of thermal expansion of the respective substrate as a function of the location of the substrate is, for example, a three-dimensional distribution function of the zero-crossing temperature over a three-dimensional substrate body.

The normalized distribution function of the zero-crossing temperature of the respective substrate is, for example, a distribution function of the zero-crossing temperature which has been normalized on the basis of a value (e.g. mean value) of the distribution function.

In a downstream step, the substrate of the optical component to be produced can then be processed so that its mean zero-crossing temperature corresponds to (i.e. is the same as) the favorable and/or optimal mean zero-crossing temperature determined in the method. By virtue of the substrate thus having the determined favorable and/or optimal mean zero-crossing temperature, thermal deformations caused by heat inputs into the mirror (e.g. by irradiation with EUV light) and associated deterioration of the imaging properties can be reduced or avoided.

The coefficient of thermal expansion specifies a change in the geometric shape and the dimensions of a material in the case of a temperature change. For example, the coefficient of thermal expansion is a linear coefficient of thermal expansion, which specifies a change in material length as a function of a change in temperature. The coefficient of thermal expansion itself is temperature-dependent, i.e. a temperature-dependent function.

At its zero-crossing temperature (ZCT), the coefficient of thermal expansion has a zero crossing in its temperature dependence, in the vicinity of which there is no thermal expansion, or only a negligible thermal expansion, of the mirror substrate material in the case of a change in temperature.

The material of the substrate of the optical component to be produced is in particular a material having a low coefficient of thermal expansion. For example, the coefficient of thermal expansion is within a range of ±20 ppb/K (parts per billion per kelvin), ±15 ppb/K, ±10 ppb/K and/or ±5 ppb/K at a desired operating temperature. However, the coefficient of thermal expansion can also be within a different range. For such a material with ultra-low thermal expansion (e.g. a substrate material sold under the name “ULE” for “Ultra-Low Expansion” by Corning Inc.), changes in geometric shape and dimensions due to temperature changes occur only to a very small extent.

Examples of the material of the substrate of the optical component to be produced comprise a glass material made of TiO₂—SiO₂, in which the ultra-low coefficient of thermal expansion is realized by varying the concentration of TiO₂. A further example is an Li₂O—Al₂O₃—SiO₂ glass ceramic (sold under the name “Zerodur” by Schott) with a crystalline phase, in which the ultra-low coefficient of thermal expansion is realized by uniformly distributed nanocrystals in a residual glass phase.

For example, step a) and/or step c) are/is also performed in computer-implemented fashion. For example, steps a), b) and/or c) are performed by a control device, e.g. a control device of one or more computers.

In step a), the one or the plurality of normalized distribution function(s) of the zero-crossing temperature are provided for example by a providing unit of the control device, e.g. also communicated to a first determining unit of the control device.

In particular, in step a) a normalized distribution function of the zero-crossing temperature as a function of the location is provided for each of the one or more optical components.

In the case of a plurality of normalized distribution functions, the plurality of normalized distribution functions differ from one another in a form and size of fluctuations in the zero-crossing temperature as a function of the location. In particular, each of the plurality of distribution functions is different from all the rest of the plurality of distribution functions. As a result of the normalizing, the plurality of distribution functions have the same mean zero-crossing temperature (e.g. a mean zero-crossing temperature of zero).

In step b), the imaging error of the optical system is determined in particular for every combination of the one or the plurality of provided normalized distribution function(s) and the plurality of predetermined mean zero-crossing temperatures. For example, if two mutually different normalized distribution functions and three mutually different values for the mean zero-crossing temperature are provided, then six possible combinations will result. Consequently, six different error values for the imaging error of the optical system are determined on the basis of the six different combinations.

In step b), therefore, a plurality of error values Fi—assigned to the normalized distribution function or to the normalized distribution functions and to the plurality of values for the mean zero-crossing temperature—of the imaging process of the optical system are determined.

In step c), the determined error values Fi are then compared with the predetermined threshold value. In particular, the mean zero-crossing temperatures associated with error values Fi which are less than the threshold value are determined as one or a plurality of selected mean zero-crossing temperature(s).

If more than one selected mean zero-crossing temperature for which the determined imaging error is less than the predetermined threshold value is determined in step c), then the substrate of the optical component to be produced can optionally be set to each of the plurality of determined selected mean zero-crossing temperatures. For example, the substrate can be heat treated for the purpose of setting its mean zero-crossing temperature on the basis of optionally each of the plurality of determined selected mean zero-crossing temperatures.

If no selected mean zero-crossing temperature for which the determined imaging error is less than the predetermined threshold value is determined in step c), then it can be determined for example that the substrate (e.g. the substrate of a plurality of representatives for optical components described below) is not suitable for producing an optical component.

For example, if the respective determined imaging error comprises a focus error of the imaging process (i.e. a deviation of an actual focus of the optical system from a target focus), then the threshold value is for example 15 nm or less, 10 nm or less and/or 5 nm or less.

For example, if the respective determined imaging error comprises an overlay error of the imaging process (i.e. a deviation of an actual position of an object imaged in an image in an image plane of the optical system with the aid of the optical system from a target position), then the threshold value is for example 3 nm or less, 1 nm or less and/or 0.5 nm or less.

For example, if the respective determined imaging error comprises a spherical wavefront error of the imaging process (i.e. a deviation of an actual wavefront of a beam guided through the optical system from an ideal spherical wave), then the threshold value is for example 200 μm or less, 100 μm or less and/or 50 μm or less (RMS deviation).

According to one embodiment, in step c) an optimal mean zero-crossing temperature for the substrate of the optical component to be produced is determined as that one of the plurality of mean zero-crossing temperatures for which the determined imaging error is minimal.

This enables even better ascertainment of the mean zero-crossing temperature for the substrate of the optical component to be produced.

For example, a plurality of selected mean zero-crossing temperatures can be determined first. Thereupon, that one of the plurality of selected mean zero-crossing temperatures for which the determined imaging error is minimal can be determined as the optimal mean zero-crossing temperature.

In step c) in this case, for example, a minimum of the plurality of error values Fi of the imaging process of the optical system determined in step b) is determined as final error FE:

$${F}_{E} = min ( {F}_{i} ) , for i = 1 to n$$

In the equation above, n denotes the number of possible combinations of the provided normalized distribution function(s) of the zero-crossing temperature and the predetermined mean zero-crossing temperatures. Consequently, n is a natural number greater than 1. Furthermore, i denotes an index that runs from 1 to n. Moreover, Fi is an imaging error determined by simulation for the i-th of the n possible combinations of the provided distribution function(s) and mean zero-crossing temperatures. F_{E} then indicates the minimum of the n imaging errors Fi determined by simulation.

The mean zero-crossing temperature associated with this minimum FE is then determined as the optimal mean zero-crossing temperature for the substrate of the optical component to be produced.

In the above example in which two mutually different normalized distribution functions and three mutually different values for the mean zero-crossing temperature are provided, thus resulting in six possible combinations, it is thus the case that n=6. Consequently, six different values Fi for the imaging error Fi of the optical system are determined on the basis of the six different combinations and the minimum thereof is determined as the final error:

$${F}_{E} = min ( {F}_{1} , {F}_{2} , {F}_{3} , {F}_{4} , {F}_{5} , {F}_{6} ) , for n = 6$$

According to a further embodiment, in step a) a plurality of normalized distribution functions of the zero-crossing temperature are provided for a corresponding substrate of a plurality of representatives for optical components.

Thus, in a case in which the distribution function of the zero-crossing temperature of the substrate of the optical component to be produced is unknown, the favorable and/or optimal mean zero-crossing temperature of the substrate of the optical component to be produced can be determined on the basis of a plurality of representative distribution functions of the zero-crossing temperature.

The plurality of representatives for optical components are for example a plurality of physically realized optical components each having a substrate with the corresponding distribution function of the zero-crossing temperature.

According to a further embodiment, in step a) a normalized distribution function of the zero-crossing temperature is provided for the substrate of the optical component to be produced.

By providing the distribution function of the zero-crossing temperature for exactly the substrate of the optical component to be produced, the favorable and/or optimal mean zero-crossing temperature for this substrate can be determined even more accurately.

If this substrate is then post-processed in a downstream step, so that its mean zero-crossing temperature corresponds to the at least one selected and/or optimal mean zero-crossing temperature determined in the method, imaging errors of the optical system as a result of heat inputs into the optical component to be produced can be reduced even further.

According to a further embodiment, the plurality of representatives are physically realized optical components, and the plurality of distribution functions of the zero-crossing temperature of the corresponding substrates of the plurality of representatives are measured.

This allows measurement results of a measurement of the distribution functions of the zero-crossing temperature of the plurality of representatives to be applied to replace the unknown distribution function of the zero-crossing temperature of the component to be produced.

According to a further embodiment, the substrate of the optical component to be produced is physically provided, and the distribution function of the zero-crossing temperature of the substrate of the optical component to be produced is measured.

For example, the substrate of the optical component to be produced is produced before step a). For example, the substrate of the optical component to be produced is produced with the distribution function of the zero-crossing temperature and an initial mean zero-crossing temperature. Furthermore, in step c) the at least one selected (i.e. favorable) and/or the optimal mean zero-crossing temperature of the substrate are/is determined. It is also possible additionally to ascertain for example an offset as the difference between the initial mean zero-crossing temperature and at least one selected and/or optimal mean zero-crossing temperature.

According to a further embodiment, the method comprises:
heat treating the substrate of the optical component to be produced for the purpose of setting a mean zero-crossing temperature of the substrate on the basis of the at least one determined selected mean zero-crossing temperature and/or the determined optimal mean zero-crossing temperature.

Thus, the substrate of the optical component to be produced can be post-processed so that its mean zero-crossing temperature corresponds to (is the same as) the at least one selected and/or optimal mean zero-crossing temperature determined in the method. In particular, the substrate can be post-processed such that its initial mean zero-crossing temperature set during the production of the substrate is corrected by the determined offset.

For example, the heat treating comprises so-called annealing of the substrate.

According to a further embodiment, respectively determining the imaging error of the optical system for each provided distribution function and for the plurality of mutually different predetermined mean zero-crossing temperatures comprises:
determining a plurality of mutually different individual errors in relation to mutually different error types of the optical system, and
determining the imaging error of the optical system on the basis of the plurality of determined individual errors.

For example, a plurality of mutually different relative individual errors are determined in relation to the mutually different error types of the optical system. Furthermore, for example the respective imaging error of the optical system is determined as a maximum, a mean value, a median and/or a quantile of the plurality of determined relative individual errors.

For example, in step c) the at least one selected mean zero-crossing temperature can also be determined as that one of the plurality of mean zero-crossing temperatures for which each of the plurality of determined individual errors is less than a corresponding predetermined individual threshold value for the corresponding error type.

In particular, the plurality of mutually different individual errors have error values for different types of individual errors.

By giving consideration to different types of individual errors of the imaging process of the optical system, the final error of the imaging process of the optical system can be determined even better for each distribution function and each offset.

Moreover, optionally—for each provided distribution function and each considered mean zero-crossing temperature—for example the maximum, the mean value, the median and/or the quantile of the plurality of determined individual errors are/is calculated and the final error of the imaging process of the optical system is subsequently taken to be this maximum, this mean value, this median and/or this quantile. This allows better consideration to be given to large error contributions. For example, the maximum of the plurality of determined individual errors is calculated on the basis of the following equation:

$${F}_{i} = max ( {f}_{k} ) , for i = 1 to n and k = 1 to m$$

In the equation above, F for i=1 to n denotes the n errors F determined by simulation in step b) for the n possible combinations of the provided distribution function(s) and mean zero-crossing temperatures. Furthermore, fₖ for k=1 to m denotes the m individual errors for a specific distribution function and a specific mean zero-crossing temperature. In this case, k is an index running from 1 to m, where m is a natural number greater than 1 and denotes the number of mutually different individual errors fₖ.

ccording to a further embodiment, the plurality of determined individual errors are weighted according to predetermined weights.

As a result, the individual errors can be weighted depending on a planned use of the optical component to be produced and of the optical system having this component. This allows error contributions to performance parameters that are particularly important to a specific application of the optical component/optical system to be kept small in a targeted manner.

For example, the maximum of the plurality of weighted individual errors is calculated on the basis of the following equation:

$${F}_{i} = max ( {f}_{k} / {W}_{k} ) , for i = 1 to n and k = 1 to m$$

In the equation above, Wₖ denotes the m weights applied for weighting the m individual errors fₖ. The weights Wₖ are in particular positive real numbers greater than 0.

According to a further embodiment, the plurality of mutually different individual errors are determined in relation to the mutually different error types and in relation to mutually different setting parameters of an illumination of the optical component to be produced of the optical system.

As a result, different setting parameters of the planned illumination of the optical component to be produced are taken into account during the computer-implemented ascertainment of the individual errors. Consequently, the different types of individual error can be determined for different simulated illumination scenarios for the optical component to be produced.

For example, the different setting parameters of the planned illumination of the optical component to be produced comprise a radiation intensity of an operating light (e.g. EUV light), which is radiated onto the optical component.

For example, the different setting parameters of the illumination can also comprise a pattern in which the operating light is radiated onto the optical component (e.g. X-dipole, Y-dipole, ring shape, DRAM profile, stripe pattern, etc.). In other words, the illumination setting parameters can comprise a heat flux distribution with heat flux poles which is caused by operating light radiated in a specific pattern onto the optical component to be produced.

For example, the different setting parameters for the illumination can also comprise a structure of a mask (e.g. lithography mask), which is imaged onto a wafer in the image plane of the optical system with the aid of the optical component to be produced.

For example, Fi can then be calculated as follows:

$${F}_{i} = max ( {f}_{k} / {W}_{l} ) , for i = 1 to n , k = 1 to m and l = 1 to q$$

In the above equation, Wᵢ denotes the weights applied for weighting the individual errors fₖ. The weights Wᵢ are in particular positive real numbers greater than zero. Furthermore, l is an index running from 1 to q, where q denotes the number of the plurality of weights Wₗ.

According to a further embodiment, the plurality of determined individual errors in relation to the mutually different error types comprise:
a deviation of an actual focus of the optical system from a target focus,
a deviation of an actual position of an object imaged in an image plane of the optical system with the aid of the optical system from a target position of the imaged object,
an image displacement of an image imaged in an image plane of the optical system with the aid of the optical system, and/or
a deviation of an actual wavefront, which images an image in an image plane of the optical system, from a target wavefront.

The individual errors are determined in computer-implemented fashion in particular, e.g. on the basis of a simulation of an imaging process using the optical system to be produced.

For example, the image displacement is a displacement of the image relative to a target position of the image. For example, the image displacement is a displacement of the image in a direction parallel to the image plane of the optical system.

The image imaged in an image plane of the optical system is for example an image imaged on a wafer of the lithography apparatus.

The actual wavefront is the wavefront of a beam guided through the optical system in particular. For example, the actual wavefront is the wavefront of the beam at the location of the image plane.

For example, the target wavefront is a spherical wave. The deviation of the actual wavefront from the target wavefront is for example a deviation from an ideal spherical wave.

According to a further embodiment, the deviation of the actual wavefront from the target wavefront comprises a tilt of the wavefront, a displacement of the wavefront, an astigmatism of the wavefront, a coma of the wavefront, a higher-order (n)-foil aberration of the wavefront and/or a spherical aberration of the wavefront.

For example, the tilt of the wavefront is a tilt about an axis (e.g. x- and/or y-axis) which is arranged parallel to the image plane of the optical system.

For example, the displacement of the wavefront is a displacement parallel to the image plane of the optical system (e.g. in the x- and/or y-direction).

The higher-order (n)-foil aberration is e.g. a trefoil aberration, a quadrafoil aberration, pentafoil aberration, hexafoil aberration, etc., of the wavefront.

According to a further embodiment, the deviation of the actual wavefront from the target wavefront is quantified in the form of Zernike polynomials.

With the aid of Zernike polynomials, it is possible to mathematically represent a deviation of a real wavefront from an ideal wavefront by a sum of polynomials. Zernike polynomials are represented with the aid of polar coordinates in a normalized unit circle. Mathematically, the individual Zernike polynomials of a circular area are characterized by polar coordinates with a power series in the radial direction ρ and a Fourier-like series in the direction of the angle Θ. In the general form Z n, ±m, n specifies the order of the polynomial in the radial direction, and m corresponds to the frequency of the angle Θ per revolution. Polynomials with even n and m=0 are rotationally symmetric, and all others are angle dependent.

For example, the Zernike polynomial Z 1, ±1 describes a tilt (+1 in the x-direction, −1 in the y-direction), the Zernike polynomial Z 2,0 describes a defocus (spherical error), the Zernike polynomial Z 2, ±2 describes an astigmatism, the Zernike polynomial Z 3, ±1 describes a coma, the Zernike polynomial Z 3, ±3 describes a trefoil aberration, the Zernike polynomial Z 4,0 describes a spherical aberration and the Zernike polynomial Z 4, ±2 describes a 4th order astigmatism.

According to a further embodiment, the optical component is a mirror, and the substrate is a mirror substrate.

The optically active surface is a reflective surface in this case in particular.

According to a further embodiment, the optical system is a projection system of the lithography apparatus.

However, the optical system can also be an illumination system of the lithography apparatus (projection exposure apparatus). The lithography apparatus can be an EUV lithography apparatus. EUV stands for “extreme ultraviolet” and denotes a wavelength of the operating light of between 0.1 nm and 30 nm. The projection exposure apparatus can also be a DUV lithography apparatus. DUV stands for “deep ultraviolet” and refers to a wavelength of the operating light of between 30 nm and 250 nm.

According to a further aspect, a computer program product is proposed, comprising instructions that, upon execution of the program by at least one computer, cause the latter to carry out the above-described method (e.g. one or more embodiments of the above-described method).

A computer program product can be provided or supplied for example as a storage medium, such as e.g. a memory card, a USB stick, a CD-ROM, a DVD, or else in the form of a downloadable file from a server in a network. For example, in a wireless communications network, this can be effected by transferring an appropriate file comprising the computer program produc.

According to a further aspect, a control device for producing an optical system for a lithography apparatus is proposed. The optical system comprises an optical component having an optically active surface and a substrate. Moreover, the control device comprises:
a providing unit for providing, for a substrate of one or more optical components, a respective normalized distribution function of a zero-crossing temperature of a coefficient of thermal expansion of the respective substrate as a function of a location of the substrate,
a first determining unit for computer-implemented determining, for each provided distribution function and for a plurality of mutually different predetermined mean zero-crossing temperatures, of an imaging error of the optical system, and
a second determining unit for determining a selected mean zero-crossing temperature for the substrate of the optical component to be produced as that one of the plurality of mean zero-crossing temperatures for which the determined imaging error is less than a predetermined threshold value.

“A” or “an” or “one” in the present case should not necessarily be understood as restrictive to exactly one element. Rather, a plurality of elements, such as for example two, three or more, can also be provided. Nor should any other numeral used here be understood to the effect that there is a restriction to exactly the stated number of elements. Rather, numerical deviations upward and downward are possible, unless indicated otherwise.

The embodiments and features described for the method, e.g. insofar as they can be performed in a computer-implemented manner, apply, mutatis mutandis, to the proposed control device, and vice versa.

Further feasible implementations of the invention also encompass not explicitly mentioned combinations of features or embodiments that are described above or hereinafter with respect to the exemplary embodiments. A person skilled in the art will also add individual aspects as improvements or supplementations to the respective basic form of the invention.

Further advantageous configurations and aspects of the invention are the subject matter of the dependent claims and also of the exemplary embodiments of the invention that are described below. The invention is explained in greater detail hereinafter on the basis of exemplary embodiments with reference to the appended figures.

### BRIEF DESCRIPTION OF THE DRAWINGS

FIG. 1 shows a schematic meridional section of a projection exposure apparatus for EUV projection lithography according to one embodiment;

FIG. 2 shows an optical system of the projection exposure apparatus from FIG. 1 according to one embodiment, the optical system comprising an optical component;

FIG. 3 shows a flowchart of a method for producing an optical system according to one embodiment;

FIG. 4 shows a substrate of the optical component from FIG. 2 according to one embodiment,

FIG. 5 shows a distribution function of a zero-crossing temperature of the substrate from FIG. 4 according to one embodiment;

FIG. 6 shows three representatives for an optical component according to one embodiment,

FIG. 7 shows distribution functions of a zero-crossing temperature of substrates of the optical components from FIG. 6 according to one embodiment;

FIG. 8 elucidates an individual error of the imaging process of the optical system from FIG. 2, determined in computer-implemented fashion, according to one embodiment;

FIG. 9 elucidates a further individual error of the imaging process of the optical system from FIG. 2, determined in computer-implemented fashion, according to one embodiment;

FIG. 10 elucidates a setting of an illumination of the optical component from FIG. 2 according to one embodiment;

FIG. 11 elucidates a weighting during the computer-implemented ascertainment of an imaging error of the optical system from FIG. 2 according to one embodiment;

FIG. 11A illustrates an imaging error of the optical system from FIG. 2 in comparison with a threshold value; and

FIG. 12 shows a control device for carrying out the method from FIG. 3 according to one embodiment.

### DETAILED DESCRIPTION

In the figures, identical or analogous or functionally identical or analogous elements have been provided with the same reference signs, unless indicated otherwise. Furthermore, it should be noted that the illustrations in the figures are not necessarily true to scale.

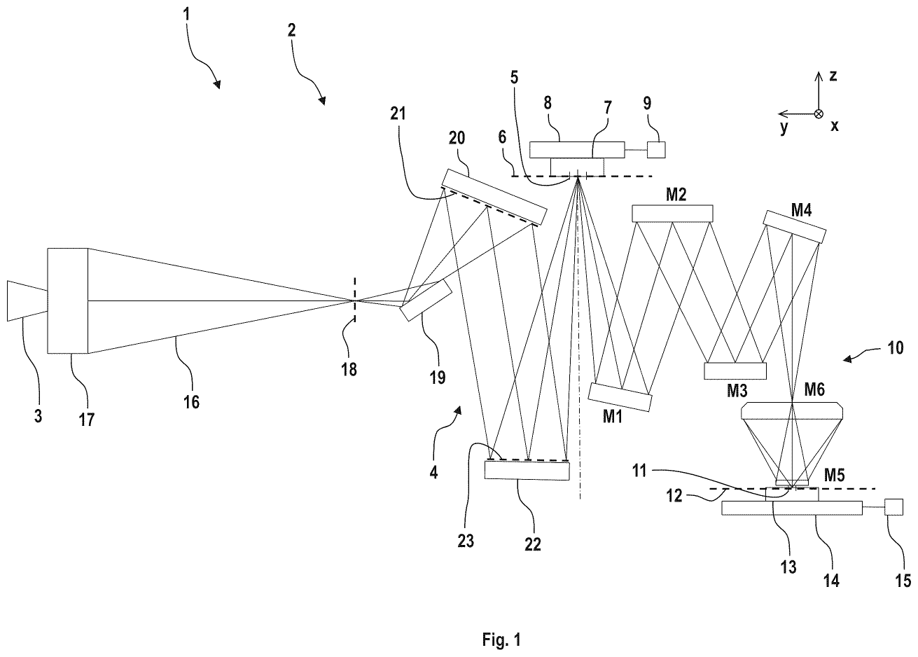

FIG. 1 shows one embodiment of a projection exposure apparatus 1 (lithography apparatus), in particular an EUV lithography apparatus. One embodiment of an illumination system 2 of the projection exposure apparatus 1 has, in addition to a light or radiation source 3, an illumination optical unit 4 for illuminating an object field 5 in an object plane 6. In an alternative embodiment, the light source 3 can also be provided as a module separate from the rest of the illumination system 2. In this case, the illumination system 2 does not comprise the light source 3.

A reticle 7 arranged in the object field 5 is exposed. The reticle 7 is held by a reticle holder 8. The reticle holder 8 is displaceable with a reticle displacement drive 9, in particular in a scanning direction.

FIG. 1 depicts, for explanation purposes, a Cartesian coordinate system with an x-direction x, a y-direction y, and a z-direction z. The x-direction x runs perpendicularly into the plane of the drawing. The y-direction y runs horizontally, and the z-direction z runs vertically. The scanning direction runs
along the y-direction y in FIG. 1. The z-direction z runs perpendicularly to the object plane 6.
   The projection exposure apparatus 1 comprises a projection optical unit 10. The projection optical unit 10 serves for imaging the object field 5 into an image field 11 in an image plane 12. The image plane 12 runs parallel to the object plane 6. Alternatively, an angle between the object plane 6 and the image plane 12 that differs from 0° is also feasible.

A structure on the reticle 7 is imaged onto a light-sensitive layer of a wafer 13 arranged in the region of the image field 11 in the image plane 12. The wafer 13 is held by a wafer holder 14. The wafer holder 14 is displaceable with a wafer displacement drive 15, in particular in the y-direction y. The displacement, firstly, of the reticle 7 with the reticle displacement drive 9 and, secondly, of the wafer 13 with the wafer displacement drive 15 can be synchronized with one another.

The light source 3 is an EUV radiation source. The light source 3 emits in particular EUV radiation 16, which is also referred to below as used radiation, illumination radiation or illumination light. The used radiation 16 has in particular a wavelength in the range of between 5 nm and 30 nm. The light source 3 can be a plasma source, for example an LPP (abbreviation for: laser produced plasma) source or a DPP (abbreviation for: gas-discharge produced plasma) source. It can also be a synchrotron-based radiation source. The light source 3 can be an FEL (abbreviation for: free-electron laser).

The illumination radiation 16 emanating from the light source 3 is focused by a collector 17. The collector 17 can be a collector with one or with a plurality of ellipsoidal and/or hyperboloidal reflection surfaces. The at least one reflection surface of the collector 17 can be impinged upon by the illumination radiation 16 with grazing incidence (abbreviated as: GI), that is to say with angles of incidence greater than 45°, or with normal incidence (abbreviated as: NI), that is to say with angles of incidence less than 45°. The collector 17 can be structured and/or coated firstly to optimize its reflectivity for the used radiation and secondly to suppress extraneous light.

Downstream of the collector 17, the illumination radiation 16 propagates through an intermediate focus in an intermediate focal plane 18. The intermediate focal plane 18 can represent a separation between a radiation source module, comprising the light source 3 and the collector 17, and the illumination optical unit 4.

The illumination optical unit 4 comprises a deflection mirror 19 and, disposed downstream thereof in the beam path, a first facet mirror 20. The deflection mirror 19 can be a plane deflection mirror or alternatively a mirror with a beam-influencing effect going beyond the pure deflection effect. Alternatively or additionally, the deflection mirror 19 can be embodied as a spectral filter separating a used light wavelength of the illumination radiation 16 from extraneous light having a wavelength that deviates therefrom. If the first facet mirror 20 is arranged in a plane of the illumination optical unit 4 which is optically conjugate to the object plane 6 as a field plane, it is also referred to as a field facet mirror. The first facet mirror 20 comprises a multiplicity of individual first facets 21, which can also be referred to as field facets. Only some of these first facets 21 are illustrated in FIG. 1 by way of example.

The first facets 21 can be embodied as macroscopic facets, in particular as rectangular facets or as facets with an arcuate or partly circular edge contour. The first facets 21 can be embodied as plane facets or alternatively as facets with convex or concave curvature.

As is known for example from DE 10 2008 009 600 A1, the first facets 21 themselves can also be composed in each case of a multiplicity of individual mirrors, in particular a multiplicity of micromirrors. The first facet mirror 20 can be embodied in particular as a microelectromechanical system (MEMS system). For details, reference is made to DE 10 2008 009 600 A1.

The illumination radiation 16 travels horizontally, i.e. along the y-direction y, between the collector 17 and the deflection mirror 19.

In the beam path of the illumination optical unit 4, a second facet mirror 22 is disposed downstream of the first facet mirror 20. If the second facet mirror 22 is arranged in a pupil plane of the illumination optical unit 4, it is also referred to as a pupil facet mirror.

The second facet mirror 22 can also be arranged at a distance from a pupil plane of the illumination optical unit 4. In this case, the combination of the first facet mirror 20 and the second facet mirror 22 is also referred to as a specular reflector. Specular reflectors are known from US 2006/0132747 A1, EP 1 614 008 B1 and U.S. Pat. No. 6,573,978.

The second facet mirror 22 comprises a plurality of second facets 23. In the case of a pupil facet mirror, the second facets 23 are also referred to as pupil facets.

The second facets 23 can likewise be macroscopic facets, which can for example have a round, rectangular or else hexagonal boundary, or can alternatively be facets composed of micromirrors. In this regard, reference is likewise made to DE 10 2008 009 600 A1.

The second facets 23 can have plane or alternatively convexly or concavely curved reflection surfaces.

The illumination optical unit 4 thus forms a doubly faceted system. This fundamental principle is also referred to as a fly's eye condenser (or fly's eye integrator).

It can be advantageous to arrange the second facet mirror 22 not exactly in a plane that is optically conjugate to a pupil plane of the projection optical unit 10. In particular, the second facet mirror 22 can be arranged so as to be tilted in relation to a pupil plane of the projection optical unit 10, as described for example in DE 10 2017 220 586 A1.

The individual first facets 21 are imaged into the object field 5 with the aid of the second facet mirror 22. The second facet mirror 22 is the last beam-shaping mirror or else actually the last mirror for the illumination radiation 16 in the beam path upstream of the object field 5.

In a further embodiment (not illustrated) of the illumination optical unit 4, a transfer optical unit contributing in particular to the imaging of the first facets 21 into the object field 5 can be arranged in the beam path between the second facet mirror 22 and the object field 5. The transfer optical unit can comprise exactly one mirror, or alternatively two or more mirrors, which are arranged one behind another in the beam path of the illumination optical unit 4. The transfer optical unit can in particular comprise one or two normal-incidence mirrors (NI mirrors) and/or one or two grazing-incidence mirrors (GI mirrors).

In the embodiment shown in FIG. 1, the illumination optical unit 4 has exactly three mirrors downstream of the collector 17, specifically the deflection mirror 19, the first facet mirror 20 and the second facet mirror 22.

In a further embodiment of the illumination optical unit 4, the deflection mirror 19 can also be omitted, and so the illumination optical unit 4 can then have exactly two mirrors downstream of the collector 17, specifically the first facet mirror 20 and the second facet mirror 22.

The imaging of the first facets 21 into the object plane 6 with the second facets 23 or using the second facets 23 and a transfer optical unit is often only approximate imaging.

The projection optical unit 10 comprises a plurality of mirrors Mi, which are consecutively numbered in accordance with their arrangement in the beam path of the projection exposure apparatus 1.

In the example illustrated in FIG. 1, the projection optical unit 10 comprises six mirrors M1 to M6. Alternatives with four, eight, ten, twelve or any other number of mirrors Mi are likewise feasible. The projection optical unit 10 is a doubly obscured optical unit. The penultimate mirror M5 and the last mirror M6 each have a passage opening for the illumination radiation 16. The projection optical unit 10 has an image-side numerical aperture that is greater than 0.5 and can also be greater than 0.6, and can be for example 0.7 or 0.75.

Reflection surfaces of the mirrors Mi can be embodied as freeform surfaces without an axis of rotational symmetry. Alternatively, the reflection surfaces of the mirrors Mi can be designed as aspherical surfaces with exactly one axis of rotational symmetry of the reflection surface shape. Just like the mirrors of the illumination optical unit 4, the mirrors Mi can have highly reflective coatings for the illumination radiation 16. These coatings can be designed as multilayer coatings, in particular with alternating layers of molybdenum and silicon.

The projection optical unit 10 has a large object-image offset in the y-direction y between a y-coordinate of a center of the object field 5 and a y-coordinate of the center of the image field 11. This object-image offset in the y-direction y can be of approximately the same magnitude as a z-distance between the object plane 6 and the image plane 12.

The projection optical unit 10 can be embodied in particular in anamorphic fashion. In particular, it has different imaging scales βx, βy in the x- and y-directions x, y. The two imaging scales βx, βy of the projection optical unit 10 are preferably (βx, βy)=(+/−0.25, +/−0.125). A positive imaging scale P means imaging without image inversion. A negative sign for the imaging scale P means imaging with image inversion.

The projection optical unit 10 consequently leads to a reduction in size with a ratio of 4:1 in the x-direction x, i.e. in a direction perpendicular to the scanning direction.

The projection optical unit 10 leads to a reduction in size of 8:1 in the y-direction y, i.e. in the scanning direction.

Other imaging scales are also feasible. Imaging scales with the same sign and the same absolute value in the x-direction x and y-direction y are also feasible, for example with absolute values of 0.125 or of 0.25.

The number of intermediate image planes in the x-direction x and in the y-direction y in the beam path between the object field 5 and the image field 11 can be the same or can differ, depending on the embodiment of the projection optical unit 10. Examples of projection optical units with different numbers of such intermediate images in the x-direction x and y-direction y are known from US 2018/0074303 A1.

In each case one of the second facets 23 is assigned to exactly one of the first facets 21 in order to form a respective illumination channel for illuminating the object field 5. In particular, this can result in illumination according to the Köhler principle. The far field is decomposed into a multiplicity of object fields 5 with the aid of the first facets 21. The first facets 21 generate a plurality of images of the intermediate focus on the second facets 23 respectively assigned to them.

The first facets 21 are each imaged onto the reticle 7 by an assigned second facet 23 with images overlaid over one another for the purpose of illuminating the object field 5. The illumination of the object field 5 is in particular as homogeneous as possible. It preferably has a uniformity error of less than 2%. Field uniformity can be achieved by overlaying different illumination channels.

The illumination of the entrance pupil of the projection optical unit 10 can be defined geometrically by an arrangement of the second facets 23. The intensity distribution in the entrance pupil of the projection optical unit 10 can be set by selecting the illumination channels, in particular the subset of the second facets 23 that guide light. This intensity distribution is also referred to as illumination setting or illumination pupil filling.

A likewise preferred pupil uniformity in the region of portions of an illumination pupil of the illumination optical unit 4 which are illuminated in a defined manner can be achieved by a redistribution of the illumination channels.

Further aspects and details of the illumination of the object field 5 and in particular of the entrance pupil of the projection optical unit 10 are described below.

The projection optical unit 10 can comprise in particular a homocentric entrance pupil. The latter can be accessible. It can also be inaccessible.

The entrance pupil of the projection optical unit 10 regularly cannot be exactly illuminated using the second facet mirror 22. In the case of imaging by the projection optical unit 10 which telecentrically images the center of the second facet mirror 22 onto the wafer 13, the aperture rays often do not intersect at a single point. However, it is possible to find an area in which the spacing of the aperture rays that is determined in pairs becomes minimal. This area constitutes the entrance pupil or an area conjugate thereto in real space. In particular, this area exhibits a finite curvature.

It may be the case that the projection optical unit 10 has different positions of the entrance pupil for the tangential beam path and for the sagittal beam path. In this case, an imaging element, in particular an optical component of the transfer optical unit, should be provided between the second facet mirror 22 and the reticle 7. With the aid of this optical element, the different position of the tangential entrance pupil and the sagittal entrance pupil can be taken into account.

In the arrangement of the components of the illumination optical unit 4 illustrated in FIG. 1, the second facet mirror 22 is arranged in an area conjugate to the entrance pupil of the projection optical unit 10. The first facet mirror 20 is arranged so as to be tilted with respect to the object plane 6. The first facet mirror 20 is arranged so as to be tilted with respect to an arrangement plane defined by the deflection mirror 19. The first facet mirror 20 is arranged so as to be tilted with respect to an arrangement plane defined by the second facet mirror 22.

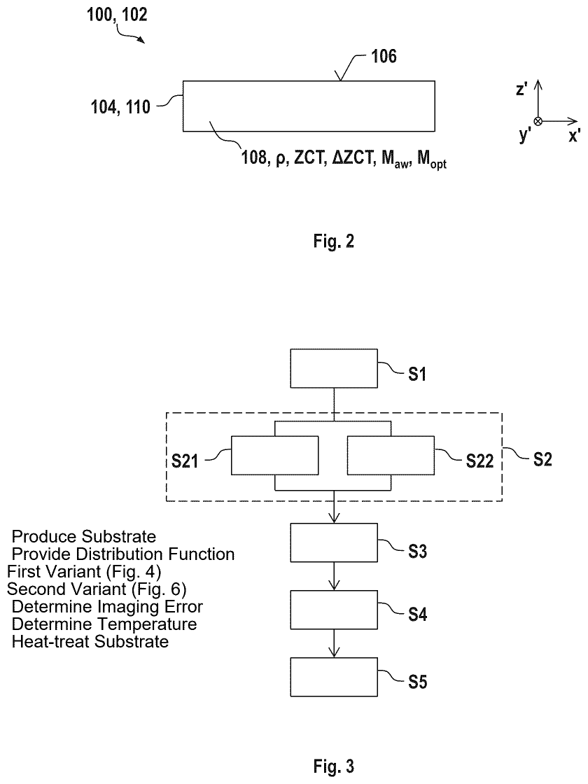

FIG. 2 shows an optical system 100 (e.g. a part of an optical system 100) having an optical component 102 according to one embodiment. The optical component 102 comprises a substrate 104 and an optically active surface 106. For example, the optical component 102 is a mirror having a mirror substrate 104 and a reflective surface 106.

For example, the optical system 100 is a projection optical unit 10 of the EUV lithography apparatus 1 (FIG. 1). However, the optical system 100 can also be an illumination optical unit 4 of the lithography apparatus 1, for example.

For example, the optical component 102 is one of the mirrors M1 to M6 of the projection optical unit 10 (FIG. 1). For example, the optical component 102 can also be one of the mirrors 19, 20, 22 of the illumination optical unit 4 (FIG. 1).

Although not shown in the figures, the optical component 102 can also be a mirror or a lens element of a DUV lithography apparatus.

The optical component 102 can heat up due to irradiation by operating light 16 (e.g. EUV light 16 of the lithography apparatus 1, FIG. 1) and absorption of the operating light 16. This may lead to a thermal deformation of the optical component 102. Imaging errors of the optical component 102 or of the optical system 100 comprising the optical component 102 may arise as a result of this thermal deformation.

High-quality substrate material 108 is used for the substrate 104 in order to reduce thermal deformation and imaging errors associated therewith. In particular, the material 108 of the substrate 104 has a very small coefficient of thermal expansion p. In particular, the material 108 has a zero-crossing temperature ZCT of the coefficient of thermal expansion p at which a thermal deformation of the mirror material depending on a temperature increase is minimal and/or zero.

On account of inhomogeneities in the material 108 of the substrate 104, the zero-crossing temperature ZCT of the substrate 104 is not distributed homogeneously over a substrate body 110 of the substrate 104; instead, it has fluctuations ΔZCT as a function of the location r of the substrate body 110. The location r of the substrate body 110 is for example a location in the three-dimensional space spanned by the directions x′, y′ and z′. A value of the mean zero-crossing temperature M of the mirror material 108 and also the variations ΔZCT of the zero-crossing temperature ZCT as a function of the location r have a direct influence on imaging errors of the optical component 102.

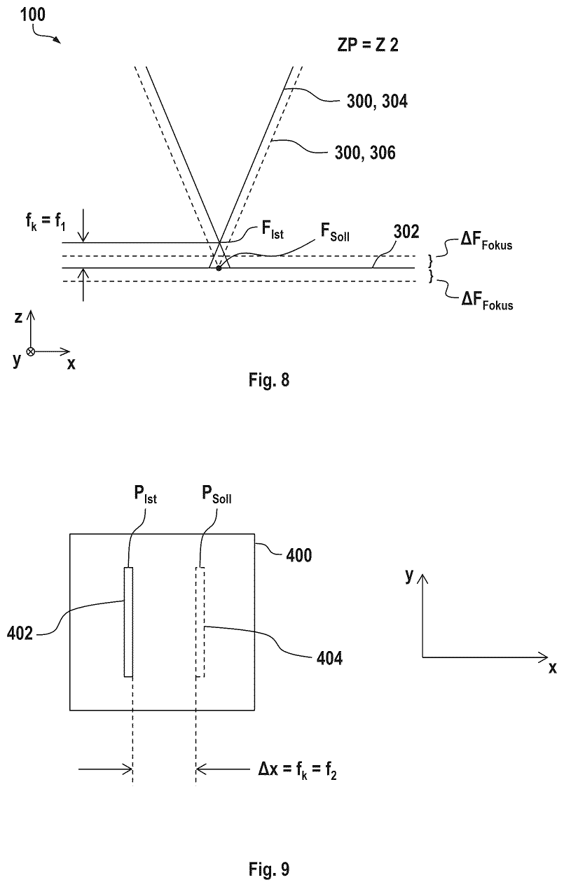

It is noted that the x′-, y′- and z′-directions or the x′-, y′- and z′-coordinate system in FIGS. 2, 4 and 6 can correspondingly match the x-, y- and z-directions or the x-, y- and z-coordinate system of FIGS. 1, 8 and 9 or can deviate therefrom. In particular, the x′-, y′- and z′-directions or the x′-, y′- and z′-coordinate system in FIGS. 2, 4 and 6 match the x-, y- and z-directions or the x-, y- and z-coordinate system of FIGS. 1, 8 and 9 only if an optical axis of the optical component 102 is arranged perpendicularly to an image plane of the optical system 100 (e.g. to the image plane 12 in FIG. 1 or image plane 302 in FIG. 8). For example, the x′-, y′- and z′-directions or the x′-, y′- and z′-coordinate system in FIGS. 2, 4 and 6 match the x-, y- and z-directions or the x-, y- and z-coordinate system of FIGS. 1, 8 and 9 if the optical component 102 is one of the mirrors M3, M5 or M6 in FIG. 1.

A method for producing an optical system 100 for a lithography apparatus 1 is described below with reference to FIGS. 2 to 11. The optical system 100 comprises the optical component 102 having the optically active surface 106 and the substrate 104 (FIG. 2).

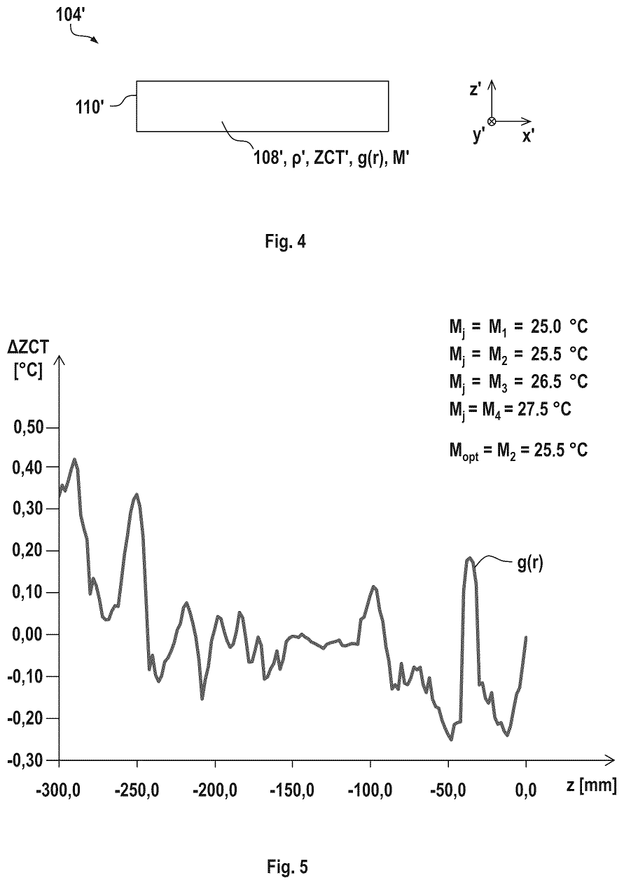

In a first step S1 of the method, the substrate 104′ is produced (FIG. 4). The produced substrate 104′ comprises a material 108′ which, on account of the production process, has a distribution function g(r) of the zero-crossing temperature ZCT′ as a function of a location r of the substrate body 110′. Furthermore, the distribution function g(r) has a mean zero-crossing temperature M′. The distribution function g(r) is considered hereinafter to be a normalized distribution function g(r) which has been normalized on the basis of a value (e.g. the mean zero-crossing temperature M′) of the actual (i.e. non-normalized) distribution function.

The production of the substrate 104′ in step S1 can be carried out before steps S2 to S4. In other examples, however, step S1 can also be carried out after one, a plurality or all of steps S2 to S4.

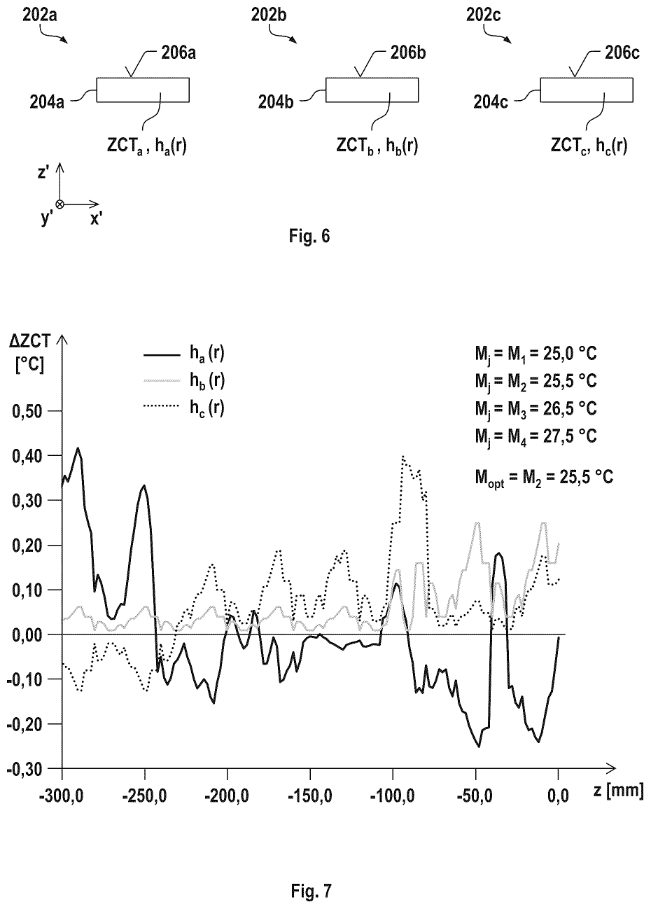

A second step S2 of the method involves providing, for a substrate (e.g. 104′ in FIG. 4 or 204a, 204b, 204c in FIG. 6) of one or more optical components (e.g. 102 in FIG. 2 or 202a, 202b, 202c in FIG. 6), a respective normalized distribution function (e.g. g(r) in FIG. 4 or hₐ(r), h_{b}(r), h_{c}(r) in FIG. 7) of a zero-crossing temperature (e.g. ZCT′ in FIG. 4 or ZCTₐ, ZCT_{b}, ZCT_{c} in FIG. 7) of a coefficient of thermal expansion of the respective substrate as a function of a location r of the substrate.

In a first variant of step S2, in step S21 a normalized distribution function g(r) of the zero-crossing temperature ZCT′ is provided for the substrate 104′ (FIG. 4) of the optical component 102 to be produced (FIG. 2). FIG. 5 illustrates an exemplary normalized distribution function g(r) of the normalized zero-crossing temperature ΔZCT of the substrate 104′ as a function of the z-location of the substrate 104′.

For example, step S1 is carried out before step S21. Then in step S21 the distribution function g(r) of the zero-crossing temperature ZCT′ of the produced substrate 104′ can be measured and normalized and the distribution function g(r) can thus be provided.

If the distribution function g(r) of the zero-crossing temperature ZCT′ of the substrate 104′ (FIG. 4) of the optical component 102 to be produced (FIG. 2) is not present and/or cannot be determined, then the second variant S22 of step S2 of the method can be carried out instead of the first variant S21.

In a second variant of step S2, in step S22 of the method a plurality of representatives 202a, 202b, 202c for optical components are provided (FIG. 6). The representatives 202a, 202b, 202c for optical components each have a substrate 204a, 204b, 204c and an optically active surface 206a, 206b, 206c.

Furthermore, in step S22 a normalized distribution function hₐ(r), h_{b}(r), h_{c}(r) of the corresponding zero-crossing temperature ZCTₐ, ZCT_{b}, ZCT_{c} is provided for each substrate 204a, 204b, 204c of the plurality of representatives 202a, 202b, 202c for optical components. FIG. 7 shows by way of example normalized distribution functions hₐ(r), h_{b}(r), h_{c}(r) of the normalized zero-crossing temperature ΔZCT of the corresponding substrate 204a, 204b, 204c as a function of the z-location of the corresponding substrate 204a, 204b, 204c.

The plurality of representatives 202a, 202b, 202c for optical components and their distribution functions hₐ(r), h_{b}(r), h_{c}(r) of the zero-crossing temperature ZCTₐ, ZCT_{b}, ZCT_{c} can be provided exclusively digitally, for example, in step S22.

Alternatively, the plurality of representatives 202a, 202b, 202c for optical components can be physically realized optical components (which are thus physically provided). In this case, their distribution functions hₐ(r), h_{b}(r), h_{c}(r) of the zero-crossing temperature ZCTₐ, ZCT_{b}, ZCT_{c} for the corresponding substrates 204a 204b, 204c can be measured and normalized in step S22.

In a third step 83 of the method, an error Fi of an imaging process of the optical system 100 is determined in computer-implemented fashion for each provided normalized distribution function g(r) in FIG. 5 or hₐ(r), h_{b}(r), h_{c}(r) in FIG. 7 and for a plurality of mutually different predetermined mean zero-crossing temperatures Mj. In this case, j is an index running from 1 to p, where p denotes a number of different mean zero-crossing temperatures Mj to be tested and is a natural number greater than one. Moreover, i denotes an index running from 1 to n, where n indicates a natural number greater than 1 and the number of possible combinations of the provided distribution function(s) and mean zero-crossing temperatures. Consequently, Fi is an error determined by simulation for the i-th of the n possible combinations of the provided distribution function(s) (e.g. g(r) in FIG. 5 or ha(r), hb(r), hc(r) in FIG. 7) and mean zero-crossing temperatures Mj.

If the first variant S21 was carried out in step S2, then in step 83 an error Fi of the imaging process of the optical system 100 is determined in computer-implemented fashion for the one provided normalized distribution function g(r) of the substrate 104′ (FIG. 5) and for a plurality of mutually different mean zero-crossing temperatures Mj. Merely by way of example, as illustrated in FIG. 5, four different mean zero-crossing temperatures Mj of 25.0° C., 25.5° C., 26.5° C. and 27.5° C. are thoroughly tested. That is to say that in the example of FIG. 5, the number of mutually different mean zero-crossing temperatures Mj is four. Moreover, the combination of a single distribution function g(r) and four different mean zero-crossing temperatures Mj yields four possible combinations. Thus i=4 and four different imaging errors Fi are calculated.

In other examples, however, a different number of values and other values for the mean zero-crossing temperature Mj can also be applied.

If the second variant S22 was carried out in step S2, then in step S3 an error Fi of the imaging process of the optical system 100 is determined in computer-implemented fashion for the plurality of provided normalized distribution functions ha(r), hb(r), hc(r) of the substrates 204a, 204b, 204c (FIGS. 6, 7) and for a plurality of mutually different mean zero-crossing temperatures Mj. Merely by way of example, as illustrated in FIG. 7, in this variant as well four different mean zero-crossing temperatures Mⱼ of 25.0° C., 25.5° C., 26.5° C. and 27.5° C. are thoroughly tested. That is to say that in the example of FIG. 7, the number of mutually different mean zero-crossing temperatures Mⱼ is also four. Furthermore, the combination of, for example, three distribution functions hₐ(r), h_{b}(r), h_{c}(r) and four different mean zero-crossing temperatures Mⱼ yields twelve possible combinations. Thus i=12 and twelve different imaging errors Fi are calculated.

Optionally, in a first variant of step S3, each error Fi can be determined on the basis of a plurality of mutually different individual errors fₖ. In particular, a plurality of individual errors fₖ which are associated with mutually different error types of the imaging process of the optical system 100 can be applied for the ascertainment of each error Fᵢ. For example, the mutually different individual errors fₖ are taken into account as relative error values. In this first variant of step S4, the error Fᵢ of the imaging process of the optical system 100 can be determined for example as a maximum of the plurality of determined individual errors fₖ, e.g. on the basis of the following equation:

$${F}_{i} = max ( {f}_{k} ) , for i = 1 to n and k = 1 to m$$

In this case, fₖ denotes the (e.g. relative) individual errors for a specific distribution function g(r) or hₐ(r), h_{b}(r), h_{c}(r) and a specific mean zero-crossing temperature Mⱼ. In this case, k is an index running from 1 to m, where m is a natural number greater than 1 and denotes the number of mutually different individual errors fₖ.

In other examples, in step S4 the error Fi of the imaging process of the optical system 100 can also be determined as a mean value, a median and/or a quantile of the plurality of determined (e.g. relative) individual errors fₖ.

The plurality of mutually different individual errors fₖ can be for example a deviation of an actual focus Fᵢₛₜ of the optical system 100 from a target focus F_{Soll} (defocus, spherical aberration, Zernike polynomial ZP of Z 2), as elucidated in FIG. 8. FIG. 8 shows a radiation 300 (e.g. the operating light 16 in FIG. 1), which is incident on an image plane 302 of the optical system 100 (FIG. 2). The target focus F_{Soll} is located in the image plane 302 in particular. The actual focus Fᵢₛₜ deviates from the target focus F_{Soll}, and so the image is blurry. A deviation of the actual focus Fᵢₛₜ from the target focus F_{Soll} represents an example of an individual error fₖ, e.g. a first (k=1) individual error f₁.

Furthermore, FIG. 8 plots an error range ΔF_{fokus} as an example of a threshold value SW (FIG. 11A) and/or individual threshold value. For example, an actual focus located in the range F_{Soll}±ΔF_{fokus} is an imaging error Fi that is less than the threshold value SW. However, the actual focus Fᵢₛₜ shown in FIG. 8 is no longer located in the permitted range F_{Soll}±ΔF_{fokus} and the associated mean zero-crossing temperature Mᵢ therefore does not satisfy the condition for a selected mean zero-crossing temperature M_{aw}. Exemplary values of an error range ΔF_{fokus} that corresponds to a threshold value SW and/or an individual threshold value for the focus for example comprise 15 nm or less, 10 nm or less and/or 5 nm or less.

For example, the plurality of mutually different individual errors fₖ can also be a displacement of a wavefront (e.g. 304 in FIG. 8) relative to a target wavefront 306, with the result that an actual position Pᵢₛₜ of an object 402 imaged in an image 400 in an image plane 302 (FIG. 8) of the optical system 100 with the aid of the optical system 100 deviates from a target position P_{Soll} of the imaged object 404, as elucidated in FIG. 9. A deviation of the actual position Pᵢₛₜ from the target position P_{Soll} (overlay error) represents a further example of an individual error fₖ, e.g. a second (k=2) individual error f₂.

In addition to or instead of individual errors fₖ in relation to the mutually different error types, the plurality of mutually different individual errors fₖ can also be individual errors fₖ in relation to mutually different setting parameters of an illumination of the optical component 102 to be produced of the optical system 100.

For example, the different setting parameters of the planned illumination of the optical component 102 to be produced comprise a radiation intensity of an operating light (e.g. EUV light 16, FIG. 1), which is radiated onto the optical component 102.

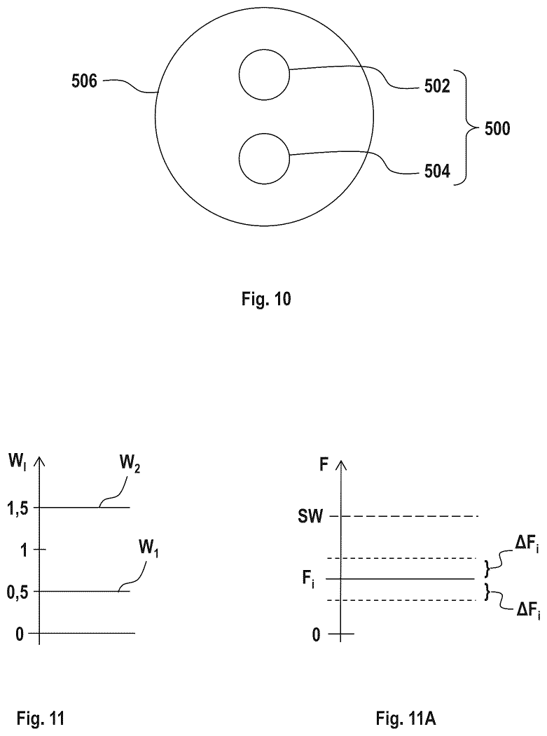

For example, the different setting parameters of the illumination can also comprise a pattern 500 or heat flux distribution 500, in which or with which the operating light 16 is radiated onto the optical component 102. By way of example, FIG. 10 elucidates two heat flux poles 502, 504 (dipole pattern) of a heat flux distribution 500 of an optically active surface 506 of an optical component (e.g. the optical component 102 in FIG. 2).

Optionally, in a second variant of step S3, the plurality of determined individual errors fk can be weighted according to predetermined weights Wl.

As a result, the individual errors can be weighted depending on a planned use of the optical component 102 to be produced and of the optical system 100 having this component 102.

In this second variant of step S3, for example, Fi is calculated as the maximum of the plurality of weighted individual errors fₖ, for example on the basis of the following equation:

$${F}_{i} = max ( {f}_{k} / {W}_{l} ) , for i = 1 to n , k = 1 to m and l = 1 to q$$

In the above equation, Wᵢ denotes the weights applied for weighting the individual errors fₖ. The weights Wᵢ are in particular positive real numbers greater than zero. Furthermore, l is an index running from 1 to q, where q denotes the number of the plurality of weights Wₗ.

In other examples, the error Fi of the imaging process of the optical system 100 can also be determined as a mean value, a median and/or a quantile of the plurality of weighted individual errors fk.

FIG. 11 illustrates weights Wl by way of example. As an example, a weight W1 equals 0.5 is illustrated, which corresponds to a high weighting, since the term Wl is in the denominator in the above equation. As a further example, a weight W2 equals 1.5 is shown, which corresponds to a low weighting.

In a case where a number p of different setting parameters for the illumination of the optical component 102 with operating light 16 are taken into consideration, it holds true that q is the mathematical product of p and m (i.e. q=p m). In a case where a plurality of different setting parameters for the illumination of the optical component 102 with operating light 16 are not taken into consideration (i.e. only a single setting is applied and therefore p=1), it holds true that q is equal to m.

For example, upon consideration of two mutually different individual errors fk (i.e. m=2) and only a single setting parameter for the illumination of the optical component 102 with operating light 16 (i.e. p=1 and q=m), then the error Fi is calculated as follows:

$${F}_{i} = max ( {f}_{k} / {W}_{l} ) , for i = 1 to n , k = 1 to 2 and l = 1 to 2$$

$${F}_{i} = max ( {f}_{1} / {W}_{1} , {f}_{2} / {W}_{2} ) , for i = 1 to n$$

In an embodiment in which, in addition to e.g. two mutually different individual errors fₖ (i.e. m=2), two mutually different setting parameters for the illumination of the optical component 102 with operating light 16 are also taken into consideration (i.e. p=2 and q=2 m), the error Fᵢ is calculated as follows:

$${F}_{i} = max ( {f}_{kd} / {W}_{l} ) , for i = 1 to n , k = 1 to 2 , d = 1 to 2 and l = 1 to 4$$

$${F}_{i} = max ( {f}_{11} / {W}_{1} , {f}_{12} / {W}_{2} , {f}_{21} / {W}_{3} , {f}_{22} / {W}_{4} ) , for i = to n$$

In this case, f_{kd} denotes the k-th individual error in the d-th illumination setting. In other words, f₁₁ denotes the first individual error f₁ in the first illumination setting, f₁₂ denotes the first individual error f₁ in the second illumination setting, f₂₁ denotes the second individual error f₂ in the first illumination setting, and f₂₂ denotes the second individual error f₂ in the second illumination setting.

A fourth step S4 of the method involves determining at least one selected mean zero-crossing temperature M_{aw} for the substrate 104 of the optical component to be produced 102 (FIG. 2) as that mean zero-crossing temperature Mⱼ for which the determined error Fi is less than a predetermined threshold value SW.

FIG. 11A illustrates by way of example an imaging error Fᵢ of the optical system 102 from FIG. 2 which is less than the predetermined threshold value SW. In this example, therefore, in step S4 the mean zero-crossing temperature Mⱼ associated with the imaging error Fᵢ is determined as the at least one selected mean zero-crossing temperature M_{aw}.

If no selected mean zero-crossing temperature M_{aw} is determined in step S4, since none of the determined imaging errors Fi is less than the predetermined threshold value SW, then it can be determined for example that the substrate 104 is not suitable for producing an optical component 102. Step 85 is not carried out in this case.

Optionally—instead of or in addition to on the basis of the threshold value SW—an optimal mean zero-crossing temperature Mopt for the substrate 104 of the optical component 102 to be produced can also be determined on the basis of a minimal imaging error Fi. In other words, in step S4 an optimal mean zero-crossing temperature Mopt for the substrate 104 of the optical component 102 to be produced (FIG. 2) can also be determined as that mean zero-crossing temperature Mj for which the determined error Fi is minimal.

In step S4 in this case, for example, a minimum F_{E} of the plurality of error values Fᵢ of the imaging process of the optical system 102 determined in computer-implemented fashion in step S3 is determined as final error F_{E} according to the following equation:

$${F}_{E} = min ( {F}_{i} ) , for i = 1 to n$$

In the equation above, n denotes the number of possible combinations of the provided normalized distribution function(s) of the zero-crossing temperature (e.g. g(r) in FIG. 4 or hₐ(r), h_{b}(r), h_{c}(r) in FIG. 7) and the predetermined mean zero-crossing temperatures tested in step S3. Moreover, F_{E} indicates the minimum of the n errors F determined by simulation.

The mean zero-crossing temperature Mj (e.g. Mj=M2=25.5° C.) associated with this minimum FE is then determined as the optimal mean zero-crossing temperature Mopt for the substrate 104 of the optical component 102 to be produced (FIG. 2).

In an optional fifth step S5 of the method, the substrate 104′ (FIG. 4) of the optical component 102 to be produced (FIG. 2) is heat treated in order to set the mean zero-crossing temperature M′ of the substrate 104′ on the basis of the at least one selected and/or optimal mean zero-crossing temperature M_{aw}, Mₒₚₜ determined in step S4. For example, the substrate 104′ is annealed with suitable parameter settings. In particular, the substrate 104′ is post-processed in step S5 such that a mean zero-crossing temperature M′ initially set during the production of the substrate 104′ is corrected by an offset between the initially set mean zero-crossing temperature M′ and the at least one selected and/or optimal mean zero-crossing temperature M_{aw}, Mₒₚₜ.

At the end of step S5, the substrate 104 (FIG. 2) produced in step S1 and post-processed in step S5 has the at least one selected and/or the optimal mean zero-crossing temperature Maw, Mopt (FIG. 2).

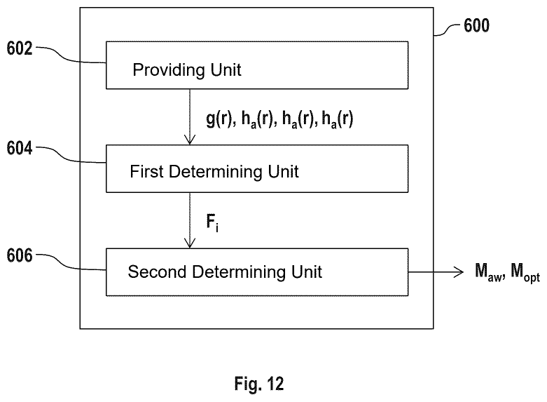

FIG. 12 shows a control device 600 for producing an optical system 100 (FIG. 2) for a lithography apparatus 1 (FIG. 1). The optical system 100 comprises an optical component 102 having an optically active surface 106 and a substrate 104 (FIG. 2).

Moreover, the control device 600 has a providing unit 602. The providing unit 602 serves for providing, for a substrate 104′, 204a, 204b, 204c of one or more optical components 102, 204a, 204b, 204c, a respective normalized distribution function g(r), ha(r), hb(r), hc(r) of a zero-crossing temperature ZCT′, ZCTa, ZCTb, ZCTc of a coefficient of thermal expansion p of the respective substrate 104′, 204a, 204b, 204c as a function of a location r of the substrate 104′, 204a, 204b, 204c.

Furthermore, the control device 600 has a first determining unit 604. The first determining unit 604 is configured to ascertain in computer-implemented fashion, for each provided distribution function g(r), ha(r), hb(r), hc(r) and for each of a plurality of mutually different predetermined mean zero-crossing temperatures Mj, an error Fi of an imaging process of the optical system 102.

Moreover, a second determining unit 606 is provided for determining at least one selected mean zero-crossing temperature Maw and/or an optimal mean zero crossing temperature Mopt for the substrate 104′, 204a, 204b, 204c of the optical component 102 to be produced as that mean zero-crossing temperature Mj for which the determined error Fi is less than a predetermined threshold value SW or minimal.

Although the present invention has been described on the basis of exemplary embodiments, it is modifiable in diverse ways.

### LIST OF REFERENCE SIGNS

1 Projection exposure apparatus
2 Illumination system
3 Light source
4 Illumination optical unit
5 Object field
6 Object plane
7 Reticle
8 Reticle holder
9 Reticle displacement drive
10 Projection optical unit
11 Image field
12 Image plane
13 Wafer
14 Wafer holder
15 Wafer displacement drive
16 Illumination radiation
17 Collector
18 Intermediate focal plane
19 Deflection mirror
20 First facet mirror
21 First facet
22 Second facet mirror
23 Second facet
100 Optical system
102 Optical component
104, 104′ Substrate
106 Optically active surface
108, 108′ Material
110, 110′ Body
202a, 202b, 202c Optical component
204a, 204b, 204c Substrate
206a, 206b, 206c Optically active surface
300 Radiation
302 Image plane

What is claimed is:

1. A method for producing an optical component for an optical system for a lithography apparatus, wherein the optical system comprises the optical component having an optically active surface and a substrate, said method comprising:
a) providing, for at least one substrate of at least one optical component, a respective normalized distribution function of a zero-crossing temperature of a coefficient of thermal expansion of the at least one substrate as a function of a location of the at least one substrate,
b) computer-implemented determining, for each of the provided distribution functions and for a plurality of mutually different predetermined mean zero-crossing temperatures, an imaging error of the optical component, and
c) determining at least one selected mean zero-crossing temperature for the substrate of the optical component to be produced as a selected one of the plurality of mean zero-crossing temperatures for which the determined imaging error is less than a predetermined threshold value.

2. The method as claimed in claim 1, wherein in said step c) an optimal mean zero-crossing temperature for the substrate of the optical component to be produced is determined as the selected one of the plurality of mean zero-crossing temperatures for which the determined imaging error is minimal.

3. The method as claimed in claim 1, wherein in said step a) a plurality of normalized distribution functions of the zero-crossing temperature are provided for a corresponding substrate of a plurality of representatives for optical components.

4. The method as claimed in claim 1, wherein in said step a) a normalized distribution function of the zero-crossing temperature is provided for the substrate of the optical component to be produced.

5. The method as claimed in claim 3, wherein the plurality of representatives are physically realized optical components, and the plurality of distribution functions of the zero-crossing temperature of the corresponding substrates of the plurality of representatives are measured.

6. The method as claimed in claim 4, wherein the substrate of the optical component to be produced is physically provided, and the distribution function of the zero-crossing temperature of the substrate of the optical component to be produced is measured.

7. The method as claimed in claim 2, further comprising:
heat treating the substrate of the optical component to be produced for setting a mean zero-crossing temperature of the substrate based on the at least one determined selected mean zero crossing temperature and/or the determined optimal mean zero-crossing temperature.

8. The method as claimed in claim 1, wherein respectively determining the imaging error of the optical component for each provided distribution function and for the plurality of mutually different predetermined mean zero-crossing temperatures comprises:
determining a plurality of mutually different individual errors in relation to mutually different error types of the optical component, and
determining the imaging error of the optical component based on the plurality of determined individual errors.
